(19) United States
(12) Patent Application Publication
(10) Pub. No.: US 2014/0137801 A1
(43) Pub. Date: May 22, 2014

(54) EPITAXIAL CHAMBER WITH CUSTOMIZABLE FLOW INJECTION

(71) Applicant: APPLIED MATERIALS, INC., Santa Clara, CA (US)

(72) Inventors: SHU-KWAN LAU, Mountain View, CA (US); ZHEPENG CONG, Vancouver, WA (US); MEHMET TUGRUL SAMIR, Mountain View, CA (US); ZHIYUAN YE, San Jose, CA (US); DAVID K. CARLSON, San Jose, CA (US); XUEBIN LI, Santa Clara, CA (US); ERROL ANTONIO C. SANCHEZ, Tracy, CA (US); SWAMINATHAN SRINIVASAN, Pleasanton, CA (US)

(73) Assignee: APPLIED MATERIALS, INC., Santa Clara, CA (US)

(21) Appl. No.: 14/047,047

(22) Filed: Oct. 7, 2013

Related U.S. Application Data
(60) Provisional application No. 61/719,009, filed on Oct. 26, 2012.

(51) Int. Cl. C23C 16/455

(52) U.S. Cl. CPC C23C 16/45563
USPC 118/728; 118/715

(57) ABSTRACT

Apparatus for processing a substrate in a process chamber are provided here. In some embodiments, a gas injector for use in a process chamber includes a first set of outlet ports that provide an angled injection of a first process gas at an angle to a planar surface, and a second set of outlet ports proximate the first set of outlet ports that provide a pressurized laminar flow of a second process gas substantially along the planar surface, the planar surface extending normal to the second set of outlet ports.

### CROSS-REFERENCE TO RELATED APPLICATIONS

This application claims benefit of U.S. provisional patent application Ser. No. 61/719,009, filed Oct. 26, 2012, which is herein incorporated by reference.

### FIELD

Embodiments of the present invention generally relate to methods and apparatus for processing a substrate.

### BACKGROUND

In some processes, such as epitaxial deposition of a layer on a substrate, process gases may be laterally flowed across a substrate surface in the same direction. For example, the one or more process gases may be flowed across a substrate surface between an inlet port and an exhaust port disposed on opposing ends of a process chamber to grow an epitaxial layer atop the substrate surface.

In some epitaxial deposition chambers, an additional side flow may be introduced in a direction perpendicular to the main gas flow path to provide additional control over the process. However, the inventors have observed that the tuning capability of the additional side flow is limited and the effective area of the additional side flow on the substrate is often restricted locally near the inject nozzles.

In addition, the inventors have observed that flow expansion at the inject nozzles of the main gas flow path can cause some of the gases to expand upward and move away from the wafer as soon as they enter the chamber. Thus, current processing apparatus and methods may fail to yield deposited films having suitable material quality, such as low defect density, composition control, high purity, morphology, in-wafer uniformity, and/or run to run reproducibility.

Accordingly, the inventors have provided improved methods and apparatus for processing substrates.

### SUMMARY

Apparatus for processing a substrate in a process chamber are provided here. In some embodiments, a gas injector for use in a process chamber includes a first set of outlet ports that provide an angled injection of a first process gas at an angle to a planar surface, and a second set of outlet ports proximate the first set of outlet ports that provide a pressurized laminar flow of a second process gas substantially along the planar surface, the planar surface extending normal to the second set of outlet ports.

In some embodiments, a process chamber for processing a substrate and having the gas injector disposed therein, may include a substrate support disposed therein to support the substrate at a desired position within the process chamber such that a processing surface of the substrate forms the planar surface; a second gas injector to provide a third process gas over the processing surface of the substrate in a second direction different from the gas flow provided by the gas injector, wherein the second gas injector includes one or more nozzles that adjust at least one of a gas flow speed, a gas flow shape, and a gas flow direction of the third process gas; and an exhaust port disposed opposite the gas injector to exhaust the first, second, and third process gases from the process chamber.

In some embodiments, an apparatus for processing a substrate may include a process chamber having a substrate support disposed therein to support a processing surface of a substrate at a desired position within the process chamber; a first injector to provide a first process gas over the processing surface of the substrate in a first direction; a second injector to provide a second process gas over the processing surface of the substrate in a second direction different from the first direction, wherein the second injector includes one or more that adjust at least one of a gas flow speed, a gas flow shape, and a gas flow direction of the third process gas; and an exhaust port disposed opposite the first injector to exhaust the first and second process gases from the process chamber.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of a process chamber in accordance with some embodiments of the present invention.

FIG. 2 depicts a schematic top view of a process chamber in accordance with some embodiments of the present invention.

FIG. 3A depicts an isometric view of an injector in accordance with some embodiments of the present invention.

FIG. 3B depicts a schematic cross-sectional top view of an injector in accordance with some embodiments of the present invention.

FIG. 3C depicts another isometric view of an injector in accordance with some embodiments of the present invention.

FIG. 3D depicts a schematic cross-sectional front view of an injector in accordance with some embodiments of the present invention.

FIGS. 4A and 4B depict a schematic top view of gas distributions over a substrate surface from an injector in accordance with some embodiments of the present invention.

FIG. 5 depicts a flow chart for method for depositing a layer on a substrate in accordance with some embodiments of the present invention.

FIG. 6 depicts a layer deposited on a substrate in accordance with the method depicted in FIG. 5.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for depositing a layer on a substrate are disclosed herein. The inventors have observed that undesirable thickness and/or compositional non-uniformities in epitaxial layers grown on a substrate surface exist during conventional processes. The inventors have further observed that such non-uniformities in thickness and composition may become even more undesirable at smaller critical dimensions and/or higher degrees of compositional loading (i.e., when growing large varieties of epitaxial layers on a substrate). Embodiments of the inventive methods and apparatus disclosed herein may advantageously overcome thickness and/or compositional non-uniformities in deposited layers by generating a flow interaction between process gases utilized for deposition. In some embodiments, edge and overall substrate surface uniformity may be improved by introducing additional gas side flow in a direction perpendicular to the main gas flow path and varying gas speeds, gas distribution areas, and gas flow directions through the use of adjustable injection nozzles.

In addition, the inventors have observed that by changing the initial velocity, mass flow rate, and/or mass of the main gas flow jet stream, the reaction location on the substrate and the rate of deposition can be tuned. For example, angled injection of a second process gas towards the surface of the substrate, while a first process gas is provided across the surface of the substrate, advantageously increases the downwards momentum of the second species of gas, which improves the mixing between first and second species of process gases. Furthermore, by providing pressurized laminar gas flow of the first process gas across the surface of the substrate through the use of restricted plenums, the concentration gradient across the substrate will be smoothed, which will enhance flow uniformity in the chamber.

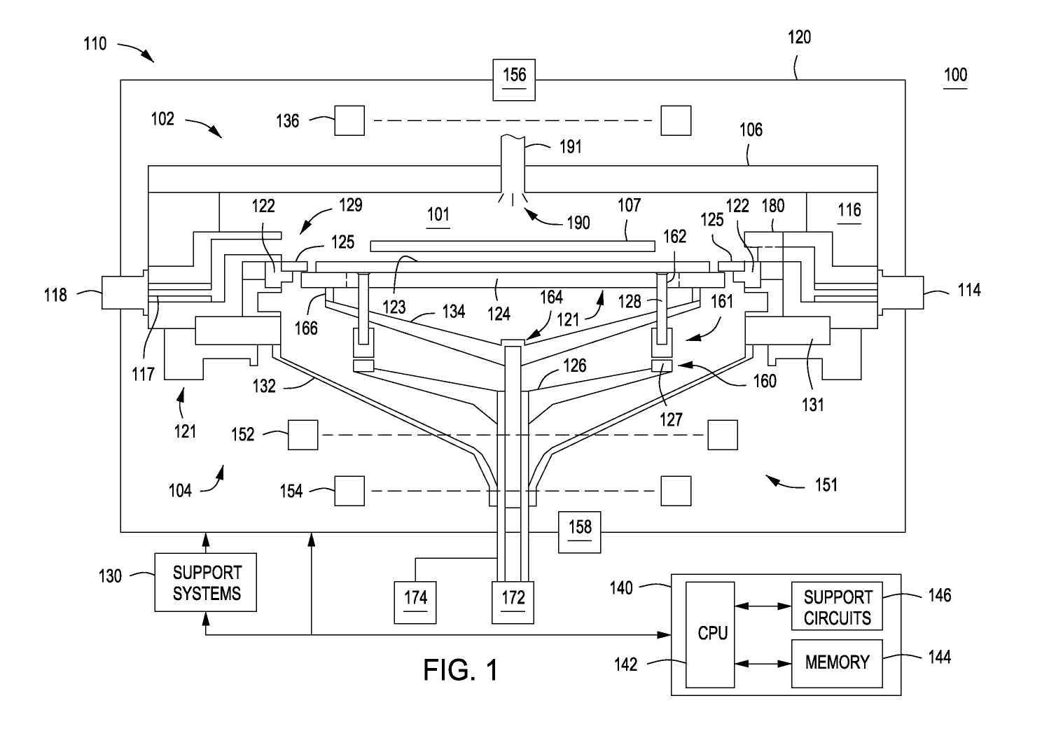

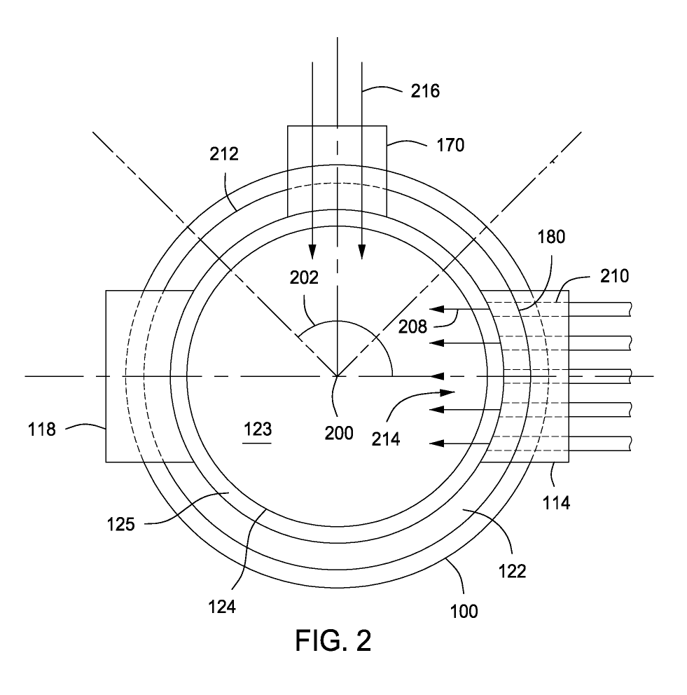

FIG. 1 depicts a schematic side view of a process chamber 100 in accordance with some embodiments of the present invention. The process chamber 100 may be modified from a commercially available process chamber, such as the RP EPIC® reactor, available from Applied Materials, Inc. of Santa Clara, Calif., or any suitable semiconductor process chamber adapted for performing epitaxial silicon deposition processes. The process chamber 100 may be adapted for performing epitaxial silicon deposition processes as discussed above and illustratively comprises a chamber body 110, a first inlet port 114 which supplies one or more gases to a first injector 180, a second injector 170, and an exhaust port 118 disposed to a second side 129 of the substrate support 124. The exhaust port 118 may include an adhesion reducing liner 117. The first injector 180 and the exhaust port 118 are disposed on opposing sides of the substrate support 124. The second injector 170 is configured with respect to the first injector 180 to provide a second process gas at an angle to a first process gas provided by the first injector 180. The second injector 170 and the first injector 180 can be separated by an azimuthal angle 202 of up to about 145 degrees on either side of the chamber, described below with respect to FIG. 2, which illustrates a top view of the process chamber 100. The process chamber 100 further includes support systems 130, and a controller 140, discussed in more detail below.

The chamber body 110 generally includes an upper portion 102, a lower portion 104, and an enclosure 120. The upper portion 102 is disposed on the lower portion 104 and includes a lid 106, a liner 116, one or more optional upper lamps 136, and an upper pyrometer 156. In one embodiment, the lid 106 has a dome-like form factor, however, lids having other form factors (e.g., flat or reverse curve lids) are also contemplated. The lower portion 104 is coupled to the first inlet port 114, the first injector 180, the second injector 170 and an exhaust port 118 and comprises a baseplate assembly 121, a lower chamber liner 131, a lower dome 132, the substrate support 124, a pre-heat ring support 122, a pre-heat ring 125 supported by pre-heat ring support 122, a substrate lift assembly 160, a substrate support assembly 164, a heating system 151 including one or more lower lamps 152 and 154, and a lower pyrometer 158. Although the term “ring” is used to describe certain components of the process chamber, such as the pre-heat ring support 122 and pre-heat ring 125, it is contemplated that the shape of these components need not be circular and may include any shape, including but not limited to, rectangles, polygons, ovals, and the like.

FIG. 2 depicts a schematic top view of the chamber 100. As illustrated, the first injector 180, the second injector 170, and the exhaust port 118 are disposed about the substrate support 124. The exhaust port 118 may be disposed on an opposing side of the substrate support 124 from the first injector 180 (e.g., the exhaust port 118 and the first injector 180 are generally aligned with each other). The second injector 170 may be disposed about the substrate support 124, and in some embodiments (as shown), opposing neither the exhaust port 118 or the first injector 180. However, the positioning of the first and second injectors 180, 170 in FIG. 2 is merely exemplary and other positions about the substrate support 124 are possible.

The first injector 180 is configured to provide a first process gas over a processing surface of the substrate 123 in a first direction 208. As used herein, the term process gas refers to both a singular gas and a mixture of multiple gases. Also as used herein, the term “direction” can be understood to mean the direction in which a process gas exits an injector port. In some embodiments, the first direction 208 is generally pointed towards the opposing exhaust port 118.

The first injector 180 may comprise a single outlet port wherein the first process gas is provided therethrough (not shown), or may comprise one or more sets of outlet ports 214, wherein each set of outlet ports 214 may include one or more outlet ports 210. In some embodiments, each set of outlet ports 214 may include about 1 to 15 outlet ports 210, although greater outlet ports may be provided (e.g., one or more). The first injector 180 may provide the first process gas, which may for example be a mixture of several process gases. Alternatively, a first set of outlet ports 214 in the first injector 180 may provide one or more process gases that are different than at least one other set of outlet ports 214. In some embodiments, the process gases may mix substantially uniformly within a plenum the first injector 180 to form the first process gas. In some embodiments, the process gases may generally not mix together after exiting the first injector 180 such that the first process gas has a purposeful, non-uniform composition. Flow rate, process gas composition, and the like, at each outlet port 210 in the one or more sets of outlet ports 214 may be independently controlled. In some embodiments, some of the outlet ports 210 may be idle or pulsed during processing, for example, to achieve a desired flow interaction with a second process gas provided by the second injector 170, as discussed below. Further, in embodiments where the first injector 180 comprises a single outlet port, the single outlet port may be pulsed for similar reasoning as discussed above.

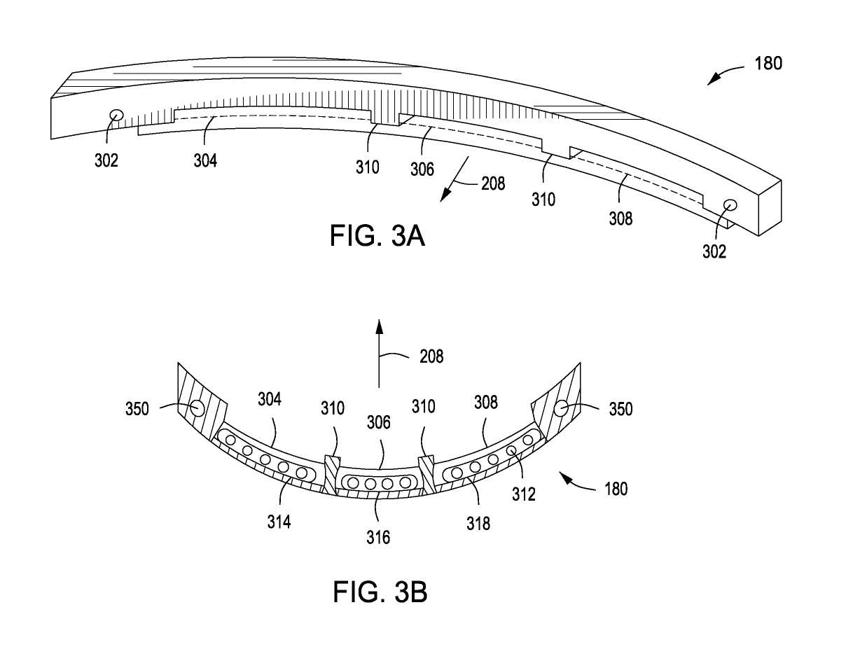

FIG. 3A depicts an isometric view of an exemplary first injector 180 in accordance with some embodiments of the present invention. First injector 180 may include a first set of outlet ports 302 and a second set of outlet ports 304, 306, 308. As shown in FIG. 3B, which depicts a schematic cross-sectional top view of injector 180, each outlet port in the second set of outlet ports 304, 306, 308 may include a plenum zone 314, 316, 318 for mixing process gases before exiting outlet ports 304, 306, 308. Each of the second set of outlet ports 304, 306, 308 and plenum zones 314, 316, 318 may be separated by a wall 310 to keep process gases between plenum zones 314, 316, 318 from mixing. The walls 310 between each plenum zone also provide the ability to control how much process gas is provided by each outlet port/plenum to facilitate more granular control of gas composition uniformity, and therefore, substrate uniformity (e.g., deposited film uniformity on the substrate). In some embodiments, process gases may enter each plenum zones 314, 316, 318 via gas inputs 312 from inlet port 114. The second set of outlet ports 304, 306, 308 eject process gases substantially parallel to and across the surface of the substrate.

In some embodiments, as shown in FIG. 3C, the first set of outlet ports 302 are configured to provide angled injection 324 of a first process gas 322 provided by conduit 350 from inlet port 114 towards the surface of the substrate. The inventors have observed that angled injection of a second process gas towards the surface of the substrate, while a first process gas is provided across the surface of the substrate (for example, via outlet ports 304, 306, 308), advantageously increases the downwards momentum of the second species of gas, which improves the mixing between first and second species of process gases. The angle 336 of the direction of the process gas from outlet port 302 may be about 70 degrees to about 90 degrees from vertical. In some embodiments, the first set of outlet ports 302 are configured to provide high flow velocity and/or mass flow rate of a process gas. The volumetric flow rate from the process gases exiting outlet port 302 may be about 0.2 standard liters per minute (slm) to about 1.0 slm per port.

In some embodiments as shown in FIG. 3C, the first injector 180 may include a lip 320 which advantageously provides a flow restriction that increases pressure in the plenum 304, 306, 308, and facilitates uniform gas exit through the second set of outlet ports 304, 306, 308. By providing pressurized laminar gas flow of a process gas across the surface of the substrate through the use of restricted plenums, the concentration gradient across the substrate will be smoothened, which will enhance flow uniformity in the chamber. In some embodiments, the flow rate of the process gases through the second set of outlet ports 304, 306, 308 may be controlled by the mass flow controllers providing gas via inlet port 114. However, in some embodiments, the lip 320 can be increased to create a smaller exit area for one or more of the second set of outlet ports 304, 306, 308 which will increase gas flow speed. In some embodiments, the volumetric flow rate from the process gases exiting outlet ports 304, 306, 308 may be about 1.0 slm to about 3.0 slm per port.

In some embodiments, the first process gas 322 flowed through the first set of outlet ports 302 may be different gas species than a second process gas flowed through the second set of outlet ports 304, 306, 308. In some embodiments, the first process gas may include one or more Group III elements in a first carrier gas. Exemplary first process gases include one or more of trimethylgallium, trimethylindium, or trimethylaluminum. Dopants and hydrogen chloride (HCI) may also be added to the first process gas. In some embodiments, the second process gas may include one or more Group III/V elements in a second carrier gas. Exemplary second process gases include one or more of diborane (B₂H₆), arsine (AsH₃), phosphine (PH₃), tertiarybutyl arsine, tertiarybutyl phosphine, or the like. Dopants and hydrogen chloride (HCl) may also be added to the second process gas.

Although different dimensions and geometries of injector 180 features may be used, some exemplary ranges of dimensions and cross-sectional geometries used in accordance with at least some embodiments are described below with respect to FIG. 3D, which depicts a schematic cross-sectional front view of injector 180. In some embodiments, the first set of outlet ports 302 may have a circular cross-section. The diameter 330 of the outlet ports 302 may be about 1 mm to about 5 mm. In some embodiments, outlets ports 302 may be coplanar with the second set of outlet ports 304, 306, 308, however, gas diffusion and mixing of the process gases from outlets ports 302 and outlet ports 304, 306, 308 may not be sufficient. Thus, in some embodiments, outlets ports 302 are generally disposed at a higher vertical level of injector 180 than outlet ports 304, 306, 308, and at a downward angle to inject process gases towards the surface of the substrate and towards/through the gas flow from outlet ports 304, 306, 308 to facilitate mixing of the gases from outlets ports 302 and outlet ports 304, 306, 308. In some embodiments, outlets ports 302 may be disposed at a height 338 of about 1 mm to about 10 mm above the top of outlet ports 304, 306, 308. In some embodiments, outlets ports 302 may be disposed at a height 334 of about 1 mm to about 10 mm above substrate 123.

In some embodiments, the second set of outlet ports 304, 306, 308 may have a rectangular cross-section, although in other embodiments different cross-sectional geometries may used. The size and shape of the outlet ports 304, 306, 308 may be defined by lip 320 and a bottom of wall 310 which contacts preheat ring support 122 to form a bottom portion of outlet ports 304, 306, 308. In some embodiments, injector 180 may be coupled to and supported by inlet port 114. In some embodiments, injector 180 may also be supported by preheat ring support 122. In some embodiments, the width 332 of the outlet ports 304, 306, 308 may be about 40 mm to about 80 mm. In some embodiments, the height 340 of the opening of outlet ports 304, 306, 308 may be about 3 mm to about 10 mm. In some embodiments, the height 340 may be based on how far lip 320 extends downward to block the opening of outlet ports 304, 306, 308. In some embodiments, the bottom of outlets ports 304, 306, 308 may be disposed at a height 342 of about 1.5 mm to about 5 mm above substrate 123.

Referring back to FIG. 2, in some embodiments the second injector 170 includes one or more adjustable nozzles configured to alter an introduction gas flow speed, gas flow shape, and gas flow direction of a process gas across the substrate 123 surface. The second injector 170 provides one or more process gases in one or more second directions 216 different from the first direction 208 provided by the first injector 180. The process gas provided by the second injector 170 may be the same, or a different species of gas as that provided by the first injector 180. In some embodiments, the second injector 170 includes one or more controllable knobs (not shown) which can be used to adjust at least one of an angle of the one or more adjustable nozzles with respect to the substrate or a cross-sectional shape of the one or more adjustable nozzles. The one or more adjustable nozzles are separately controllable such that each nozzle may be adjusted to inject gas at different angles. In some embodiments, the one or more adjustable nozzles are separately controllable to provide different flow rates and distribution area by adjusting a cross-sectional shape of the one or more adjustable nozzles. In addition, the cross-sectional shape of the one or more adjustable nozzles, and/or the angle of injection, may be optimized to target a specific radius zone on the substrate. The second injector 170 may inject the one or more process gases at a height of about 1 mm to about 10 mm above the substrate 123.

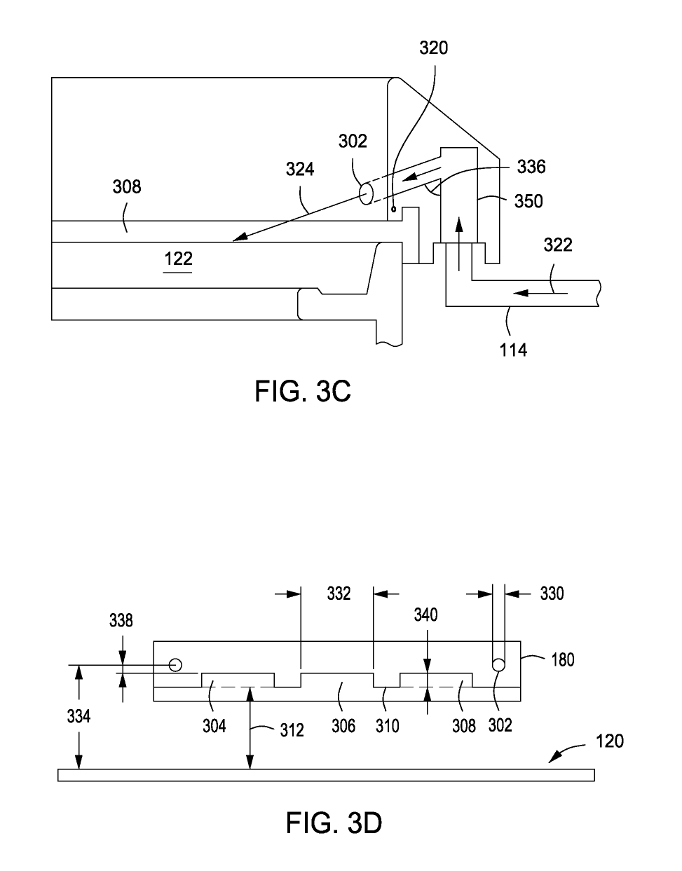

In some embodiments, the second injector 170 may comprise a single adjustable nozzle 402 as shown in FIG. 4A. The adjustable nozzle 402 may provide a process gas, which may for example be a mixture of several process gases, to be flowed across the surface of the substrate 123. The single adjustable nozzle 402 may be an adjustable slot nozzle having a rectangular cross-section. The height of the adjustable slot nozzle opening may be about 0.5 mm to about 10 mm. The width of the adjustable slot nozzle opening is about 2 mm to about 25 mm. Other cross-sectional areas for the adjustable nozzle may be used depending on the distribution area 414 of the gas over the substrate being targeted as well as process conditions such as pressure and total flow of process gases for specific process. The angle of injection and the cross-section area of the slot nozzle may be adjusted using the controllable knobs discussed above. In some embodiments, a relationship between the first direction 208 of the first injector 180 and the second direction 216 of the second injector 170 can be at least partially defined by an azimuthal angle 202. The azimuthal angle 202 is measured between the first direction 208 and the second direction 216 with respect to a central axis 200 of the substrate support 124. The azimuthal angles 202 may be up to about 145 degrees, or between about 0 to about 145 degrees. The azimuthal angles 202 may be selected to provide a desired amount of cross-flow interaction between the process gases from second injector 170 and process gases from the first injector 180.

Alternatively, the second inlet port may 170 comprise a plurality of adjustable nozzles 404, 406 as shown in FIG. 4B. Each of the plurality of adjustable nozzles 404, 406 may provide a process gas, which may for example be a mixture of several process gases. Alternatively, one or more of the plurality of adjustable nozzles 404, 406 may provide one or more process gases that are different than at least one other of the plurality of adjustable nozzles 404, 406. In some embodiments, the process gases may mix substantially uniformly after exiting the second injector 170 to form the second process gas. In some embodiments, the process gases may generally not mix together after exiting the second injector 170 such that the second process gas has a purposeful, non-uniform composition. The one or more adjustable nozzles 404, 406 are separately controllable such that each nozzle may be adjusted to inject gas at different angles. In some embodiments, the one or more adjustable nozzles 404, 406 are separately controllable to provide different flow rates and distribution area by adjusting a cross-sectional shape of the one or more adjustable nozzles 404, 406. In addition, the cross-sectional shape of the one or more adjustable nozzles 404, 406, and/or the angle of injection, may be optimized to target a specific radius zone on the substrate. The cross sectional shape of the adjustable nozzles 404, 406 may be rectangular, circular, or other cross-sectional areas depending on the distribution areas 416, 418 of the gas over the substrate being targeted. In some embodiments, the second injector 170, or some or all of the adjustable nozzles 402, 404, 406 may be idle or pulsed during processing, for example, to achieve a desired flow interaction with a process gas provided by the first injector 180.

Returning to FIG. 1, the substrate support assembly 164 generally includes a support bracket 134 having a plurality of support pins 166 coupled to the substrate support 124. The substrate lift assembly 160 comprises a substrate lift shaft 126 and a plurality of lift pin modules 161 selectively resting on respective pads 127 of the substrate lift shaft 126. In one embodiment, a lift pin module 161 comprises an optional upper portion of the lift pin 128 is movably disposed through a first opening 162 in the substrate support 124. In operation, the substrate lift shaft 126 is moved to engage the lift pins 128. When engaged, the lift pins 128 may raise the substrate 123 above the substrate support 124 or lower the substrate 123 onto the substrate support 124.

The substrate support 124 further includes a lift mechanism 172 and a rotation mechanism 174 coupled to the substrate support assembly 164. The lift mechanism 172 can be utilized for moving the substrate support 124 along the central axis 200. The rotation mechanism 174 can be utilized for rotating the substrate support 124 about the central axis 200.

During processing, the substrate 123 is disposed on the substrate support 124. The lamps 136, 152, and 154 are sources of infrared (IR) radiation (i.e., heat) and, in operation, generate a pre-determined temperature distribution across the substrate 123. The lid 106 and the lower dome 132 are formed from quartz; however, other IR-transparent and process compatible materials may also be used to form these components.

The support systems 130 include components used to execute and monitor pre-determined processes (e.g., growing epitaxial silicon films) in the process chamber 100. Such components generally include various sub-systems. (e.g., gas panel(s), gas distribution conduits, vacuum and exhaust sub-systems, and the like) and devices (e.g., power supplies, process control instruments, and the like) of the process chamber 100. These components are well known to those skilled in the art and are omitted from the drawings for clarity.

The controller 140 generally comprises a central processing unit (CPU) 142, a memory 144, and support circuits 146 and is coupled to and controls the process chamber 100 and support systems 130, directly (as shown in FIG. 1) or, alternatively, via computers (or controllers) associated with the process chamber and/or the support systems.

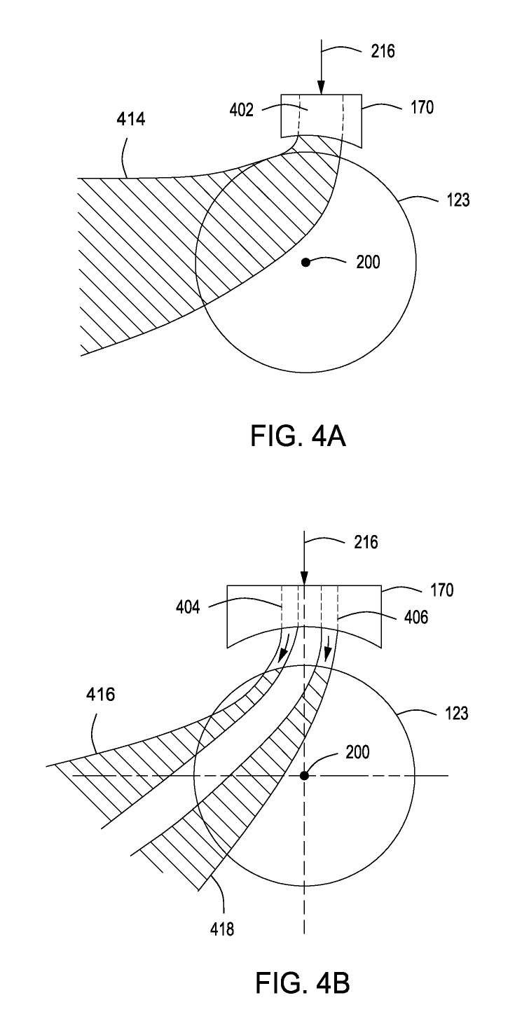

FIG. 5 depicts a flow chart for a method 500 of depositing a layer 600 on the substrate 123. The method 500 is described below in accordance with embodiments of the process chamber 100. However, the method 500 may be used in any suitable process chamber capable of providing the elements of the method 500 and is not limited to the process chamber 100.

The method 500 begins at 502 by providing a substrate, such as the substrate 123. The substrate 123 may comprise a suitable material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, or the like. Further, the substrate 123 may comprise multiple layers, or include, for example, partially fabricated devices such as transistors, flash memory devices, and the like.

At 504, the first process gas may be flowed across the processing surface of the substrate 123 in a first direction, for example, in a first direction 208. The first process gas may be flowed from the first injector 180, or from one or more of the pressurized laminar outlet ports 304, 306, 308 in the first direction 208 and across the processing surface towards the exhaust port 118. The first process gas may be flowed from the first injector 180 in the first direction 208 parallel to the processing surface of the substrate 123. The first process gas may comprise one or more process gases. For example, the first process gases may include trimethylgallium. In some embodiments, the gases injected using pressurized laminar outlet ports 304, 306, 308 may be, for example, gases that have uniform growth rates (i.e., slow cracking rates).

At 506, the second process gas may be flowed through high flow velocity outlet ports 302 down towards the processing surface of the substrate 123 at a downward angle. As discussed above in accordance with the embodiments of the chamber 100, the downward angle may be about 70 degrees to about 90 degrees from vertical. The second process gas may be the same or different from the first process gas. The second process gas may comprise one or more process gases. For example, the second process gases may include tertiarybutyl arsine. In some embodiments, the gases injected using high flow velocity outlet ports 302 may be, for example, gases that have non-uniform growth rates (i.e., fast cracking rates).

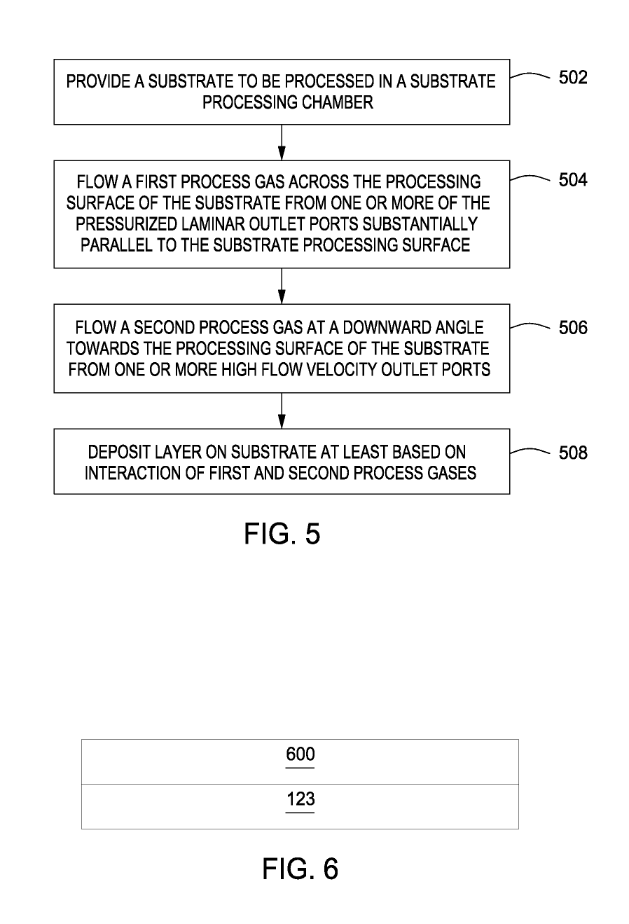

At 508, a layer 600 (shown in FIG. 6) is deposited atop the substrate 123 at least partially from the flow interaction of the first and second process gases. In some embodiments, the layer 600 may have a thickness between about 1 to about 10,000 nanometers. In some embodiments, the layer 400 comprises silicon and germanium. The concentration of germanium in the layer 400 may be between about 5 to about 100 atomic percent (i.e., germanium only). In one specific embodiment, the layer 600 is a silicon germanium (SiGe) layer having a germanium concentration of between about 25 to about 45 atomic percent.

The layer 600 may be deposited by one or more processing methods. For example, the flow rates of the first and second process gases may be varied to tailor the thickness and/or composition of the layer 600. Further, the flow rates may be varied to adjust crystallinity of the layer. For example, a higher flow rate may improve crystallinity of the layer. Other process variants can include rotating about and/or moving the substrate 123 along the central axis 200 while one or both of the first and second process gases are flowing. For example, in some embodiments, the substrate 123 is rotated while one or both of the first and second process gases are flowing. For example, in some embodiments, the substrate 123 is moved along the central axis 200 while one or both of the first and second process gases are flowing to adjust the flow rates of each process gas.

Other variants of depositing the layer are possible. For example, the first and second process gases may be pulsed in one of an alternating or cyclical pattern. In some embodiments, selective epitaxial growth of the layer may be performed by alternately pulsing deposition and etch gases from either or both of the first and second injectors 180, 170. Further, pulsing of the first and second process gases could occur in combination with other processing methods. For example, a first pulse of one or both of the first and second process gases may occur at a first substrate position along the central axis 200, and then a second pulse of one or both of the first and second process gases may occur at a second substrate position along the central axis 200. Further, pulsing can occur with the substrate is rotating about the central axis 200.

Thus, methods and apparatus for depositing a layer on a substrate have been disclosed herein. The inventive methods and apparatus advantageously overcome thickness and/or compositional non-uniformities the deposited layer by generating a flow interaction between process gases utilized for deposition. The inventive methods and apparatus further reduce defect/particle formation in the deposited layer, and allow for the tailoring of thickness and/or composition and/or crystallinity of the deposited layer.

While the foregoing is directed to embodiments of the present invention, other and further embodiments of the invention may be devised without departing from the basic scope thereof.

1. A gas injector for use in a process chamber, comprising:
a first set of outlet ports that provide an angled injection of a first process gas at an angle to a planar surface; and
a second set of outlet ports proximate the first set of outlet ports that provide a pressurized laminar flow of a second process gas substantially along the planar surface, the planar surface extending normal to the second set of outlet ports.

2. The gas injector of claim 1, wherein the first and second process gases are a same species of gases.

3. The gas injector of claim 1, wherein the first and second process gases are different species of gases.

4. The gas injector of claim 1, wherein the first set of outlet ports is disposed at a different vertical level of the gas injector than the second set of outlet ports.

5. The gas injector of claim 1, wherein the first set of outlet ports and the second set of outlet ports are disposed at a same coplanar level of the gas injector.

6. The gas injector of claim 1, wherein each outlet port in the second set of outlet ports includes a plenum zone.

7. The gas injector of claim 6, wherein an exit area of each of plenum zone is partially blocked by a lip that increases pressure and flow uniformity of the second process gas.

8. The gas injector of claim 1, wherein the first set of outlet ports is comprised of a plurality holes that provide the first process gas at a high flow velocity towards the planar surface.

9. A processing chamber to process a substrate, comprising:
a substrate support to support the substrate such that a processing surface of the substrate forms a planar surface;
a first gas injector comprising:
a first set of outlet ports that provide an angled injection of a first process gas at an angle to the planar surface of the substrate; and
a second set of outlet ports proximate the first set of outlet ports that provide a pressurized laminar flow of a second process gas substantially along the planar surface, the planar surface extending normal to the second set of outlet ports;
a second gas injector to provide a third process gas over the processing surface of the substrate in a second direction different from a gas flow provided by the first gas injector, wherein the second gas injector includes one or more adjustable nozzles that adjust at least one of a gas flow speed, a gas flow shape, and a gas flow direction of the third process gas; and
an exhaust port disposed opposite the first gas injector to exhaust the first, second, and third process gases from the process chamber.

10. An apparatus for processing a substrate, comprising:
a process chamber having a substrate support disposed therein to support a processing surface of a substrate at a desired position within the process chamber;
a first injector to provide a first process gas over the processing surface of the substrate in a first direction;
a second injector to provide a second process gas over the processing surface of the substrate in a second direction different from the first direction, wherein the second injector includes one or more nozzles that adjust at least one of a gas flow speed, a gas flow shape, and a gas flow direction of the third process gas; and
an exhaust port disposed opposite the first injector to exhaust the first and second process gases from the process chamber.

11. The apparatus of claim 10, wherein the one or more nozzles are adjustable nozzles and wherein the apparatus further includes one or more controllable knobs that adjust at least one of an angle of the one or more adjustable nozzles with respect to the substrate or a cross-sectional shape of the one or more adjustable nozzles.

12. The apparatus of claim 11, wherein the cross-sectional shape of the one or more adjustable nozzles is optimized to target a specific radius zone on the substrate.

13. The apparatus of claim 11, wherein the angle of the one or more adjustable nozzles is optimized to target a specific radius zone one the substrate.

14. The apparatus of claim 13, wherein the second injector includes one adjustable slot nozzle.

15. The apparatus of claim 14, wherein the one adjustable slot nozzle provides a second gas at an azimuthal angle measured between the first direction and the second direction with respect to a central axis of the substrate support of up to about 145 degrees.

16. The apparatus of claim 14, wherein the one slot nozzle has a rectangular cross section.

17. The apparatus of claim 16, wherein a height of the adjustable slot nozzle opening is about 0.5 mm to about 10 mm, and a width of the adjustable slot nozzle opening is about 2 mm to about 25 mm.

18. The apparatus of claim 13, wherein the second injector includes a plurality of adjustable nozzles.

19. The apparatus of claim 18, wherein each of a first adjustable nozzle and a second adjustable nozzle in the plurality of adjustable nozzles are separately controllable by the one or more controllable knobs.

20. The apparatus of claim 19, wherein the first adjustable nozzle provides the second process gas at a different angle than the second adjustable nozzle.
